(19) United States
(12) Patent Application Publication
(10) Pub. No.: US 2025/0183861 A1
(43) Pub. Date: Jun. 5, 2025

(54) DUMMY LOAD FOR A WIRELESS TRANSMISSION ARRANGEMENT

(71) Applicant: Infineon Technologies AG, Neubiberg (DE)

(72) Inventors: Ljudmil ANASTASOV, München (DE); Alexander BELITZER, München (DE)

(21) Appl. No.: 18/953,303

(22) Filed: Nov. 20, 2024

(30) Foreign Application Priority Data
Nov. 30, 2023 (DE) 102023212042.9

(51) Int. Cl. H03F 3/24; G01S 7/03

(52) U.S. Cl. CPC H03F 3/245; G01S 7/03; H03F 2200/451

(57) ABSTRACT

A power amplifier arrangement, for one or more antennae, with a calibratable dummy load. The power amplifier arrangement includes a calibration arrangement that controls or defines an amount of power drawn by the dummy load responsive to a power-responsive parameter that changes responsive to an amount of power drawn by one or more power amplifiers of the power amplifier arrangement when amplifying an input signal to be transmitted by the antenna(e).

### CROSS-REFERENCE TO RELATED APPLICATION

This application claims priority to Germany Patent Application No. 102023212042.9 filed on Nov. 30, 2023, the content of which is incorporated by reference herein in its entirety.

### TECHNICAL FIELD

The present disclosure relates to the field of wireless transmission arrangements, and in particular to wireless transmission arrangements comprising a dummy load arrangement.

### BACKGROUND

Wireless transmission arrangements, such as those configured for radar applications, often contain a power amplifier arrangement for amplifying signals for transmission by one or more antennae. Typically, the power amplifier arrangement is supplied with a power input from a power management arrangement.

It is recognized that control schemes for the wireless transmission arrangement can demand sudden changes in whether or not any amplified signals are to be generated for transmission by the antenna(e). For instance, there may be a desire to radiate one or more bursts of electromagnetic radiation, e.g., a sequence of pulses or chirps. Without any additional power control, this will cause the power drawn by the power amplifier arrangement to suddenly change, e.g., undergo step changes. Such sudden changes can introduce noise into the power management arrangement, e.g., caused by ringing, which currently require relatively large filtering circuitry to mitigate.

One known technique to reduce the impact of a change in demand for any amplified signals is to integrate a dummy load arrangement into the power amplifier arrangement. The dummy load arrangement is controlled to draw power (e.g., current) when the demand for amplification drops or reduces. This effectively reduces the size of a step change in the power drawn by the power amplifier arrangement in between the amplification of any input signals for transmission.

There is an ongoing desire to improve the performance of a power amplifier arrangement for a wireless transmission arrangement.

### SUMMARY

Examples disclosed herein propose a power amplifier arrangement for amplifying signals for transmission by one or more antennae of a wireless transmission arrangement. The power amplifier arrangement includes an input interface, one or more power amplifiers, a dummy load arrangement, a power control arrangement, and a calibration arrangement.

The input interface is configured to receive an input signal. Each power amplifier is configured to: when activated, amplify the input signal and provide the amplified input signal to a respective antenna of the wireless transmission arrangement; and when deactivated, prevent the provision of the amplified input signal to the respective antenna of the wireless transmission arrangement. The dummy load arrangement is configured to: when activated, draw an electrical current from the input interface; and when deactivated, draw no or negligible electrical current from the input interface. The power control arrangement is configured to controllably activate and deactivate the one or more power amplifiers and the dummy load arrangement, wherein the power control arrangement is configured to controllably switch between: an antenna output mode, in which the power control arrangement activates the one or more power amplifiers and deactivates the dummy load arrangement; and an antenna block mode, in which the power control signal activates the dummy load arrangement and deactivates the one or more power amplifiers. The calibration arrangement includes: a sensing arrangement configured to sense a value of one or more power-responsive parameters that changes responsive to a power drawn by the one or more power amplifiers when activated; and a current control arrangement configured to control, responsive to the sensed value of the one or more power-responsive parameters, a magnitude of the electrical current drawn by the dummy load arrangement when activated.

Examples of the present disclosure provide a power amplifier arrangement for a wireless transmission arrangement, such as a radar system. The power amplifier arrangement is configured to drive or power one or more antennae for the wireless transmission system or radar system. A power amplifier arrangement may be integrated into a microwave management integrated circuit (MMIC), alternatively labelled a monolithic microwave integrated circuit (MMIC), which may include other circuit components required for signal processing (e.g., oscillators and the like).

The power amplifier arrangement includes a set of one or more power amplifiers.

Each power amplifier includes one or more amplifying stages (e.g., op-amps) for amplifying an input power to drive a respective antenna. Commonly, the frequency of the input power will change or be controlled in order to control the frequency of the electromagnetic signal output by the antenna. This can be performed by one or more oscillators.

There may be a desire to operate one or more antennae in bursts or chirps, in which the antenna(e) will periodically transmit an electromagnetic signal with intervening gaps. Thus, there is a power control arrangement that will control whether or not power is provided to the antenna. This is achieved by switching between an antenna output mode (in which the appropriate power amplifier(s) is/are activated to provide the power to its respective antenna) and an antenna block mode, in which the appropriate power amplifier(s) is/are deactivated to prevent the provision of power to the respective antenna.

The power amplifier(s) will draw more current from the input power during the antenna output mode than during the antenna block mode. This can create significant noise in the power amplifier arrangement (particularly ringing in any filters) without appropriate filtering and/or current control.

The present approach proposes to provide a dummy load arrangement that is activated during the antenna block mode. More particularly, the present approach proposes to calibrate the dummy load arrangement responsive to a power (e.g., current) drawn by the power amplifier(s) during the antenna output mode. This significantly reduces a change in current drawn from the input power when switching between the antenna output mode and the antenna block mode. This significantly attenuates any noise, reduces interference and minimizes a risk of any out-of-band emission of electromagnetic radiation by the antenna(e).

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 illustrates a wireless transmission arrangement comprising a power amplifier arrangement.

FIG. 2 illustrates a power amplifier.

FIG. 3 illustrates a power drawn by the power amplifier arrangement.

FIG. 4 illustrates an alternative power amplifier.

FIG. 5 illustrates a method performed by a proposed calibration arrangement.

FIG. 6 illustrates an alternative wireless power amplifier arrangement.

FIG. 7 illustrates a proposed power amplifier arrangement.

### DETAILED DESCRIPTION

The examples described herein provide a power amplifier arrangement, for one or more antennae, with a calibratable dummy load. The power amplifier arrangement comprises a calibration arrangement that controls or defines an amount of power drawn by the dummy load responsive to a power-responsive parameter that changes responsive to an amount of power drawn by one or more power amplifiers of the power amplifier arrangement when amplifying an input signal to be transmitted by the antenna(e).

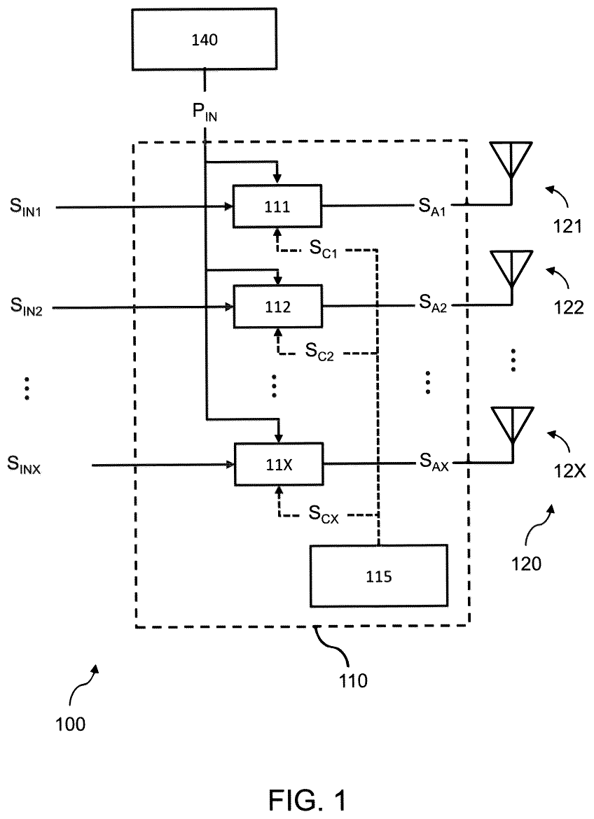

FIG. 1 illustrates a wireless transmission arrangement 100 in which one or more examples may be employed, for the sake of improved contextual understanding. The wireless transmission arrangement may be configured for operating as a radar system such as an FMCW radar system.

The wireless transmission arrangement 100 comprises a power amplifier arrangement 110 (comprising one or more power amplifiers 111, 112, . . . , 11X); an antenna arrangement 120 (comprising one or more antennae 121, 122, . . . , 12X); and a power management arrangement 140.

The power amplifier arrangement 110 and the power management arrangement 140 may together form a portion of a power supply arrangement for a wireless transmission arrangement.

The power amplifier arrangement 110 comprises a power control arrangement 115 that controls the operation of the power amplifier arrangement 110. More specifically, the power control arrangement 115 controls the number of one or more power amplifiers 111, 112, . . . , 11X that are activated.

The power control arrangement 115 is operable in an antenna output mode, in which it controls the power amplifier arrangement 110 to amplify one or more input signals S_{IN1}, S_{IN2}, . . . , S_{INX}, using a respective one or more power amplifiers, to produce a respective one or more amplified input signals S_{A1}, S_{A2}, . . . , S_{AX}. In the antenna output mode, each amplified input signal S_{A1}, S_{A2}, . . . , S_{AX} is provided to a respective antenna 121, 122, . . . , 12X of the antenna arrangement 120. Each respective antenna will, when receiving an amplified input signal, radiate an electromagnetic signal or wave responsive to the amplified input signal. The operation of an antenna is well known in the art, and is not described in detail for the sake of conciseness.

Thus, the properties of each input signal S_{IN1}, S_{IN2}, . . . , S_{INX} (e.g., frequency, amplitude and/or temporal patterns) define the properties of each radiated electromagnetic signal. Approaches for generating a suitable input signal (e.g., using one or more oscillators) are well known in the art, and may depend upon the precise use-case scenario for the wireless transmission arrangement, and are not described in detail for the sake of conciseness.

The power control arrangement 115 may control the operation of each power amplifier 111, 112, . . . , 11X using a respective set of one or more control signals S_{C1}, S_{C2}, . . . , S_{CX}. Each set of control signals may, for instance, control activation and/or deactivation of one or more switches in each power amplifier. The power control arrangement 115 may operate according to any suitable or desired control scheme for controlling when the antenna(e) is/are to radiate an electromagnetic signal.

The power management arrangement 140 is configured to provide an input power P_{IN} to the power amplifier(s) of the power amplifier arrangement 110. The input power P_{IN} allows the power amplifier arrangement to perform an amplification of each input signal S_{IN1}, S_{IN2}, . . . , S_{INX}. The input power P_{IN} may be carried by a power line. The input power P_{IN} may be the power of a power supply signal of the power amplifier arrangement 110. The input power P_{IN} may be, at least during the amplification by the power amplifier arrangement, a DC signal which may be stable or slightly varying (e.g., having a ripple) during the antenna output mode.

It will be appreciated that the power control arrangement 115 is also operable in an antenna block mode, in which it controls the power amplifier arrangement to not provide any amplified input signals S_{A1}, S_{A2}, . . . , S_{AX} to the antenna(e) of the antenna arrangement 120. This can be performed, for instance, by disconnecting the power amplifiers from any input signal and/or redirecting a power drawn by the power amplifiers (e.g., to a dummy load, as later exemplified). As previously mentioned, control can be performed using the set(s) of one or more control signal(s) S_{C1}, S_{C2}, . . . , S_{CX}.

Of course, the antenna output mode and the antenna block mode are only example modes of operation for the power control arrangement.

For instance, the antenna output mode may be subdivided into a plurality of different sub-modes, each producing a different number and/or combination of one or more amplified input signals. As one example, one sub-mode of an antenna output mode is a full output mode, in which all input signals are amplified and provided to a respective antenna. As another example, another sub-mode of the antenna output mode is a first antenna output mode, in which only the input signal for a first antenna 121 of the antenna arrangement 120 is amplified and provided to the first antenna (with no other input signals being amplified). Other variations will be readily apparent to the skilled person.

In the context of a wireless transmission arrangement 100 for a radar system, the power amplifier arrangement may form part of a microwave management integrated circuit (MMIC) and the power management arrangement 140 may form part of a power management integrated circuit (PMIC). The power amplifier arrangement 110 and the power management arrangement 140 may together form a portion of a radar power supply arrangement (e.g., for the radar system).

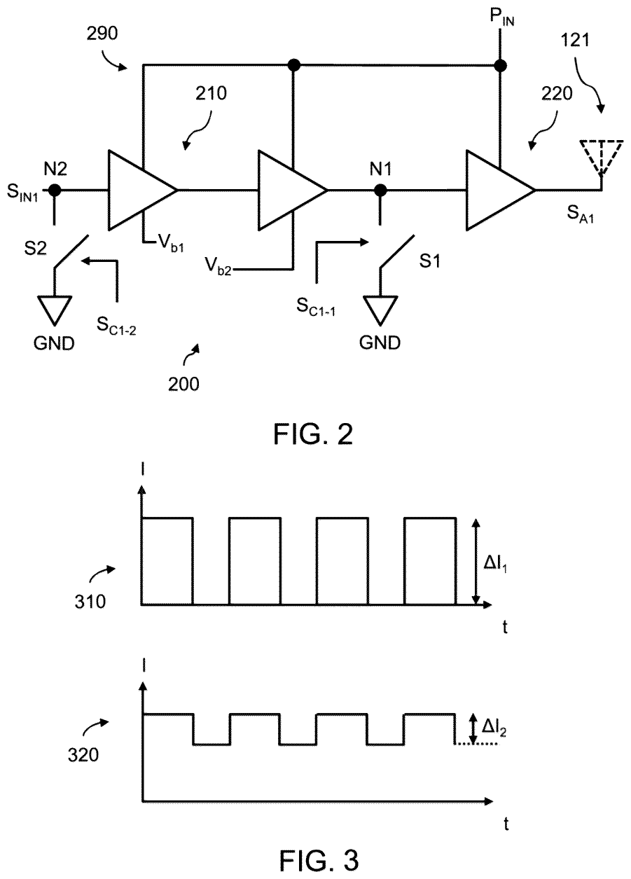

FIG. 2 illustrates a power amplifier 200 for a power amplifier arrangement. The power amplifier is controllable by a power control arrangement (not shown) to amplify an input signal S_{IN1}, received at an input interface N2, to produce an amplified input signal S_{A1}.

Although not forming part of the power amplifier or power amplifier arrangement, the antenna 121 driven by the power amplifier 200 is illustrated for the sake of clarity.

The power amplifier 200 comprises a first series 210 of one or more amplifying stages (here: 2 amplifying stages, but in practice any number) connected between the input interface N2 and an intermediate node N1. The power amplifier also comprises a second series 220 of one or more amplifying stages (here: a single stage, but in practice any number) connected between the intermediate node N1 and the respective antenna 121 for the power amplifier 200.

Each amplifying stage is powered or driven by the input power P_{I}m. The input power P_{IN} may be carried by a power line 290.

FIG. 2 also illustrates a dummy load arrangement in the form of a diverting switch S1. The diverting switch is connected between the intermediate node N1 of the respective power amplifier 200 and a ground or return path GND. When the diverting switch S1 is activated, the power amplifier will not output an amplified input signal S_{A1} to the antenna 121. Rather, the (partially) amplified input signal will be diverted to the ground or return path. Thus, when the diverting switch S1 is activated, the power amplifier will continue to draw power, but will not provide the amplified input signal S_{A1} to the antenna 121.

FIG. 2 also illustrates an optional second diverting switch S2 connected between the input interface N2 and a ground or return path GND. This second diverting switch S2, when activated, will prevent the power amplifier (and dummy load arrangement) from drawing power. This facilitates increase control over the operation of the power amplifier. In particular, when integrated into a power amplifier arrangement, this facilitates control over which power amplifiers perform the amplifying function.

The operation of the diverting switch(es) is controlled by the power control arrangement (not shown), e.g., via a set of one or more control signals S_{C1-1}, S_{C1-2}.

Thus, the power control arrangement is able to controllably activate and deactivate the power amplifier and the dummy load arrangement. This is through control of the diverting switch(es).

Turning back to FIG. 1, in some circumstances, there is a desire to cause the antenna arrangement to radiate one or more electromagnetic signal(s) (e.g., radar signals) in a series or sequence of pulses or chirps. Intervening gaps will separate the pulses/chirps in the sequence. Operating the antenna arrangement in this way may be referred to as a burst mode of operation.

For instance, for performing a radar function, there may be a desire to emit radar signal in series of chirps or “chirp pulses”, in which a frequency of the radar signal in each chirp changes (e.g., ramps up) from a start frequency to a stop frequency. The duration of each chirp may be in the range from a few microseconds up to a few milliseconds, e.g., 50 μs to 2,000 μs. The actual values may be, however, greater or lower dependent on the application. Accordingly, the pulses or chirps may include a frequency ramp used in frequency modulated continuous wave (FMCW) radar to detect at least one of a range, a speed or an angle of arrival of signals reflected from objects.

One approach for facilitating the chirping or pulsing functionality is to keep the power control arrangement in the antenna output mode, and to control the input signal(s) to perform the desired chirps with intervening gaps. However, maintaining the power control arrangement in the antenna output mode will generate significant interference in the radiated electromagnetic signals (as they will continue to radiate energy in the intervening gaps).

Another approach for facilitating this chirping or pulsing functionality for the radiated electromagnetic signal(s) is to control the power control arrangement to alternate between the antenna output mode and the antenna block mode for the duration of the desired pulsing of the electromagnetic signal(s). More specifically, the power control arrangement may operate in the antenna output mode during a chirp and operate in the antenna block mode in between chirps (e.g., in any intervening interval between chirps). This significantly reduces interference.

It is recognized that, if the input signal(s) for producing the pulsing electromagnetic signal(s) were to be wholly disconnected from the power amplifier(s) between pulses, then the power drawn by each power amplifier would suddenly drop. In particular, a current drawn by each power amplifier will suddenly decrease between the chirps. This sudden drop in the power (and particularly current) drawn by the power amplifier(s) can create significant noise in the power amplifier arrangement and the power management arrangement, particularly ringing in any filters, if no filtering is provided.

It is also recognized that one approach to reducing the impact of this sudden drop in power is to configure the power amplifier arrangement to draw a non-zero amount of current in between the chirps. This can be facilitated by activating the dummy load arrangement (e.g., illustrated in FIG. 2) during the antenna block mode.

It is noted that the power control arrangement may also be operable in an amplifier block mode, in which the power amplifier(s) is/are controlled to draw no or negligible current with the dummy load arrangement being deactivated. This can be facilitated by activating the second diverting switch (e.g., illustrated in FIG. 2), e.g., of each power amplifier, during the antenna block mode. Such a mode may be used in between bursts (frames) of chirps, e.g., during a processing phase. More particularly, such a technique may be advantageous for use during a processing phase of a radar operation or functionality.

FIG. 3 illustrates the current I drawn by a power amplifier arrangement over time t, in different circumstances, during a burst mode of operation for the antenna arrangement. The illustrated waveforms are used to demonstrate the effect of switching between an antenna output mode and an antenna block mode.

As previously explained, during a “chirp” or a “pulse”, the power control arrangement operates in the antenna output mode. In between chirps or pulses, the power control arrangement operates in the antenna block mode. This prevents the antenna(e) from radiating electromagnetic signals in between chirps.

A first waveform 310 illustrates the current drawn by the power amplifier arrangement when the power amplifier arrangement is configured to draw no or negligible current between chirps or pulses and no dummy load arrangement is activated (e.g., during the antenna block mode). During the antenna output mode, the current may be stable at a value or may change slightly during one chirp or pulse. During the antenna block mode, there is a significant drop in the current drawn, which can cause noise in the power amplifier arrangement and/or power management arrangement. In other words, there is a significant difference ΔI₁ between the current drawn during a chirp and the current drawn between chirps.

In the context of the present disclosure, a negligible current is one that has a magnitude of less than 5%, and in other examples less than 1%, of the current drawn by an electrical element when operational or activated.

A second waveform 320 illustrates the current drawn by the power amplifier arrangement when a dummy load arrangement is activated in between chirps or pulses (e.g., during the antenna block mode). The drop in the current drawn by the power amplifier arrangement is significantly reduced or attenuated. In particular, the dummy load arrangement will draw some power that was previously drawn by the power amplifier(s) in producing the amplified input signal(s). This significantly reduces a value in the difference ΔI₂ between the current drawn during a chirp and the current drawn between chirps.

In the following text, a further improvement to this technique will be described.

In particular, as illustrated by the second waveform, it has been recognized that even if the dummy load arrangement is used (e.g., in between chirps or during the antenna block mode), there is still a noticeable drop in the current drawn, e.g., the value of ΔI₂ is significant. Thus, noise is still present or provided when the power control arrangement switches from the antenna output mode to the antenna block mode.

It is proposed to supplement a power amplifier arrangement with a calibration arrangement comprising a sensing arrangement and a current control arrangement. In practice, the calibration arrangement may form part of the power control arrangement.

The sensing arrangement is configured to sense a value of one or more power-responsive parameters that changes responsive to a power drawn by the one or more power amplifiers when activated.

The current control arrangement is configured to control, responsive to the sensed value of the one or more power-responsive parameters, a magnitude of the electrical current drawn by the dummy load arrangement when activated. Thus, the dummy load arrangement is calibratable so as to have a calibratable or modifiable electrical current draw when activated. The current control arrangement defines the magnitude of current drawn by the dummy load arrangement when activated.

FIG. 5 is a simplified flowchart illustrating a method 500 performed by the calibration arrangement.

The method 500 comprises a step 510 of sensing or monitoring a value of one or more power-responsive parameters that changes responsive to a power drawn by the one or more power amplifiers when activated (e.g., during the antenna output mode of the power control arrangement). Step 510 is performed by the sensing arrangement.

The method 500 also comprises a step 520 of controlling, responsive to the sensed value of the one or more power-responsive parameters, a magnitude of the electrical current drawn by the dummy load arrangement when activated. Step 520 is performed by the current control arrangement.

In examples, the current control arrangement may be configured to increase the current drawn by the dummy load arrangement, when activated, responsive to the value of the power-responsive parameter (e.g., during the antenna output mode of the power control arrangement) indicating an increase to the power drawn by the one or more power amplifiers when activated. This significantly reduces a difference between the power drawn by the power amplifier arrangement during the antenna output mode and the antenna block mode of the power control arrangement.

In examples, the power-responsive parameter is responsive to the power drawn by the overall power amplifier arrangement. In such examples, the current control arrangement may be configured to match (e.g., minimize or reduce an error/difference between) the value of the power-responsive parameter during the antenna block mode (of the power control arrangement) with the value of the power-responsive parameter during the antenna output mode (of the power control arrangement). This can act to effectively reduce the value of the difference between the current drawn in the antenna output mode and the current drawn in the antenna block mode.

Thus, step 520 may be adapted to further comprise monitoring the value of the one or more power-responsive parameters during the antenna block mode, and controlling the current responsive to the monitored value during the antenna block mode, e.g., to match that of the value of the power-responsive parameter(s) during the antenna output mode.

In this way, step 520 may comprise performing feedback control of at least the current through the dummy load arrangement (during the antenna block mode) to reduce or minimize a difference between the (average) current drawn by the dummy load arrangement when activated (e.g., during the antenna block mode) and the (average) current drawn by the one or more power amplifiers when activated (e.g., during the antenna output mode). In this way, a mismatch between the current drawn by the power amplifier(s) when activated (e.g., producing an amplified input signal) and a current drawn by the dummy load arrangement when activated (e.g., when no amplified input signal is produced) is calibrated.

The proposed approach (which provides an antenna block mode) avoids the transmission of electromagnetic radiation between desired emissions of electromagnetic radiation, which might otherwise interfere or disturb desired radiation.

The use of a dummy load arrangement also acts to significantly reduce the settling time of the power supply for the power amplifier arrangement, because the load jump is significantly lower. This improves the quality of amplification.

The calibration arrangement may be integrated into the previously disclosed power amplifier arrangement, power supply arrangement and/or wireless transmission arrangement.

In examples, there is provided a radar power supply arrangement comprising a herein described power amplifier arrangement comprising the calibration arrangement and a power management arrangement. The power amplifier arrangement may form a portion of a microwave management integrated circuit (MMIC), alternatively labelled a monolithic microwave integrated circuit (MMIC). The power management arrangement may form part of a power management integrated circuit (PMIC).

A number of example approaches for controlling the power drawn by the dummy load arrangement are hereafter described.

With reference to FIG. 2, in one example when the dummy load arrangement is (at least partially) integrated into (each of) a first set of one or more power amplifiers, then controlling the magnitude of the electrical current drawn by the dummy load arrangement may be performed by controlling, responsive to the sensed value of the power-responsive parameter, a biasing of one or more of the first series of amplifying stages of the first set of one or more power amplifiers when the dummy load arrangement is activated.

Controlling a biasing of each of the first series of amplifying stages may be performed, for instance, by controlling a voltage bias V_{b1}, V_{b2} for each amplifying stage. Controlling a biasing of the amplifying stage(s) facilitates a control over the current drawn by the first series of amplifying stages whilst the dummy load arrangement is activated.

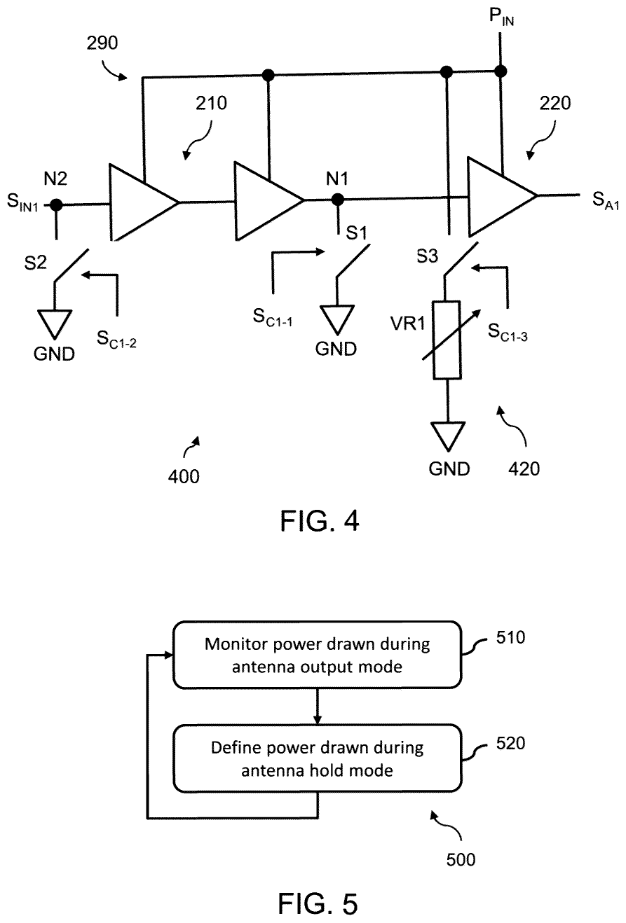

FIG. 4 illustrates an alternative power amplifier 400 in which an alternative dummy load arrangement 420 is integrated. Elements of the power amplifier 400 that are otherwise identical to the previously disclosed power amplifier retain their corresponding reference numerals.

In this example, the dummy load arrangement 420 comprises a third diverting switch S3 connected between the power line 290 and a first variable resistor VR1 of the dummy load arrangement 420. The first variable resistor VR1 connects the third diverting switch S3 to a ground or return path GND.

This third diverting switch S3, when activated by a corresponding control signal S_{C1-3} (by the power control arrangement), will divert a power flow through the first variable resistor VR1. The resistance of the first variable resistor VR1 may be controlled, by the current control arrangement, to thereby control the power drawn by the first variable resistor, and thereby the dummy load arrangement. This facilitates control over the power drawn by the dummy load arrangement.

Thus, the resistance of the first variable resistor VR1 can be controlled responsive to the sensed value of the one or more power-responsive parameters, to thereby control a magnitude of the electrical current drawn by the dummy load arrangement 420 when activated. Thus, the dummy load arrangement 420 is calibratable so as to have a calibratable or modifiable electrical current draw when activated.

The first variable resistor VR1 may be replaced by any other electrical component for which a current drawn by the electrical component is controllable, e.g., a current source or the like.

The previously described examples effectively integrate the dummy load arrangement into the one or more power amplifiers. The integration of the dummy load arrangement into the one or more of the power amplifiers provides a more compact power amplifier arrangement and allows for more granular or finer control over the power drawn by the dummy load arrangement. Such techniques allow for flexible control over which portions of the dummy load arrangement are active at any given time, allowing for flexibility over the operation of the dummy load arrangement.

More particularly, the previously described examples integrate a portion of a dummy load arrangement into each power amplifier. This facilitates improved control over the current drawn by the dummy load arrangement.

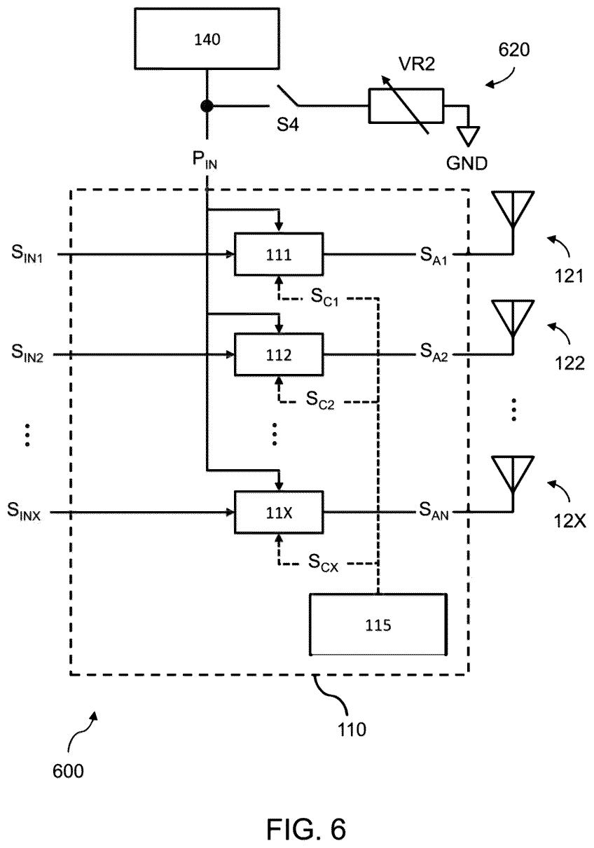

FIG. 6 illustrates a power amplifier arrangement 600 comprising a further example of a dummy load arrangement 620.

In this example, the dummy load arrangement 620 comprises a fourth diverting switch S4 connected to the power line that provides power to all the power amplifiers. The dummy load arrangement 620 further comprises a second variable resistor VR2 connected to a ground or return path GND. The resistance of the variable resistor VR2 can be controlled, so as to facilitate control or calibration of the current or power drawn by the variable resistor. The dummy load arrangement is activated by activating the fourth diverting switch. The current control arrangement may accordingly be configured to modify or adjust a magnitude of the resistance of the second variable resistor in order to control or define a magnitude of the electrical current drawn by the dummy load arrangement when activated.

The second variable resistor VR2 may be replaced by any other electrical component for which a current drawn by the electrical component is controllable, e.g., a current source or the like.

Other suitable examples of a calibratable dummy load arrangement for use in examples will be clear to the skilled person. More particularly, alternative circuits and circuit components having a controllable current flow will be readily apparent.

A wide variety of different power-responsive parameters and control schemes are envisaged in the present disclosure.

Examples of suitable power-responsive parameters include: a power drawn by the power amplifier arrangement (e.g., during the antenna output mode); a power or current drawn by each power amplifier of the power amplifier arrangement (e.g., during the antenna output mode); a temperature of the power amplifier arrangement (which changes responsive to a power drawn); and/or a control parameter of the power management arrangement that defines the input power (such as a duty cycle of a pulse-width modulation (PWM) for generating the input power).

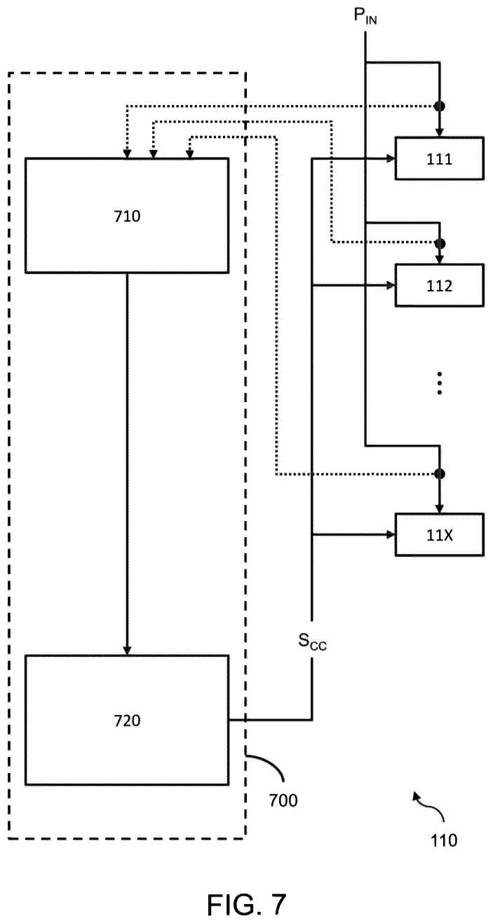

FIG. 7 illustrates a portion of an example power amplifier arrangement 110 for illustrating a calibration arrangement 700 that makes use of a first example of a power-responsive parameter. For the sake of illustrative clarity, the input signal(s), the amplified input signal(s), and the control signal(s) for each power amplifier 111, 112, . . . , 11X have not been illustrated.

The calibration arrangement 700 comprises a sensing arrangement 710 and a current control arrangement 720.

The sensing arrangement 710 is configured to sense a value of one or more power-responsive parameters that changes responsive to a power drawn by the one or more power amplifiers when activated.

The current control arrangement 720 is configured to control, responsive to the sensed value of the one or more power-responsive parameters, a magnitude of the electrical current drawn by the dummy load arrangement when activated. This can be achieved, for instance, by using a set S_{CC} of one or more current control signals, e.g., to adjust: a biasing of one or more amplifying stages, a resistance of a variable resistor, or any other suitable mechanism for adjusting a current drawn by a dummy load arrangement.

In this example, the power-responsive parameter is the (e.g., average) current drawn by all power amplifiers 111, 112, . . . , 11X during the antenna output mode. This may, as illustrated, be calculated by individually sensing the current drawn by each power amplifier when activated and summing the individually sensed current(s) to determine the value of the power-responsive parameter.

Thus, the sensing arrangement 710 is configured to sense a magnitude of an electrical current drawn by the one or more power amplifiers when activated as one of the one or more power responsive parameters. This value can be labelled an “output mode current”, as it represents the current drawn by the power amplifier(s) during the output mode.

In one example, the sensing arrangement 710 comprises a single sensing element for sensing a magnitude of a current at an input to the sensing element; and a multiplexing arrangement configured to sequentially connect each power amplifier, when activated, to the input to the sensing element to thereby sequentially sense the current drawn by each power amplifier when activated. The sensed currents can then be summed to produce the value for one of the power-responsive parameters.

In other examples, the sensing arrangement 710 comprises a respective sensing element for each power amplifier, each sensing element configured to sense the current drawn by the respective power amplifier when activated. The sensed currents (by all the sensing elements) can then be summed to produce the value for one of the power-responsive parameters.

In another example, the sensing arrangement comprises a sensing element configured to monitor the current drawn by the power amplifier whilst the power control arrangement is in the antenna output mode. Thus, the overall current drawn by the power amplifier(s) may be monitored.

One example of a (single or respective) sensing element is a current mirror. Other approaches can be derived by the skilled person based on the present disclosure.

In some examples, the current control arrangement 720 may be configured to match the magnitude of the electrical current drawn by the dummy load arrangement when activated (e.g., the output mode current) to the magnitude of the electrical current drawn by the one or more power amplifiers when activated (e.g., a “block mode current”). In this way, as the magnitude of the output mode current increases, so does the block mode current.

If the dummy load arrangement is integrated into the power amplifier(s), monitoring the block mode current can be achieved by, for instance, also monitoring (using the same sensing arrangement 710) the electrical current drawn by the power amplifier(s) during the antenna block mode. This can be achieved using a same or similar approach to that used to monitor the current drawn by the power amplifier(s) during the antenna block mode. The block mode current may be compared to the output mode current to perform (closed-loop) feedback control of the block mode current, e.g., to match the output mode current, by controlling the current drawn by the dummy load arrangement during the antenna block mode with the current control arrangement 720.

If the dummy load arrangement is not integrated into the power amplifier(s), monitoring the block mode current can be achieved by monitoring the electrical current drawn by the dummy load arrangement during the antenna block mode. This can be achieved using a current sensor, e.g., positioned in series with the dummy load arrangement. The block mode current may be compared to the output mode current to perform (closed-loop) feedback control of the block mode current, e.g., to match the output mode current, by controlling the current drawn by the dummy load arrangement during the antenna block mode with the current control arrangement 720.

In some examples, it may not be necessary to perform closed-loop feedback in this way. Rather, an open-loop feedback control scheme could be used, e.g., where the current drawn by the dummy load arrangement is performed using only the value of the power-responsive parameter.

As another example of a power-responsive parameter, the sensing arrangement may be configured to sense a voltage of the power drawn by the one or more power amplifiers, when the one or more power amplifiers are activated, as one of the one or more power responsive parameters. Voltage sensing can be readily performed, for instance, using an analogue-to-digital converter connecting to an appropriate node of a conductor that carries the power drawn by the one or more power amplifiers (e.g., a power line), as would be readily apparent to the skilled person.

A voltage of the power drawn by the one or more power amplifiers will change responsive to the current drawn by the power amplifier. Thus, monitoring this/these voltage(s) facilitates sensing of a parameter that changes responsive to the power drawn by the one or more power amplifiers.

Accordingly, the current control arrangement may be configured to adjust the magnitude of the electrical current drawn by the dummy load when activated responsive to the voltage of the power drawn by the one or more power amplifiers at the input interface changing.

As another example of a power-responsive parameter, the sensing arrangement may be configured to sense a temperature of the power drawn by the one or more power amplifiers (e.g., when the one or more power amplifiers are activated).

The temperature of the power amplifier(s) will increase with an increasing amount of power drawn by the power amplifier(s). This provides a power-responsive parameter that can be used to control or define the current drawn by the dummy load arrangement during the antenna block mode. In particular, if the temperature during the antenna block mode increases, then the current control arrangement may increase the current drawn by the dummy load arrangement when activated (e.g., during the antenna block mode).

The power-responsive parameter is not limited to a parameter that can be monitored in or on the power amplifier arrangement.

As another example, the power-responsive parameter may be a parameter of a power management arrangement configured to generate the input power for the one or more amplifiers.

For instance, in an example in which the power management arrangement is configured to generate the input power using pulse-width modulation, the sensing arrangement is configured to sense, as the power-responsive parameter, a PWM parameter that changes responsive to a change in one or more properties of the pulse-width modulation performed by the power management arrangement. This may, for instance, comprise a duty cycle of the pulse-width modulation performed by the power management arrangement.

This approach recognizes that the functionality of other elements of the wireless transmission arrangement will vary to control, or depending upon, the power drawn by the one or more power amplifiers during the antenna output mode of the power control arrangement. The property/properties of such components can be used as a power-responsive parameter(s).

A number of the previously described examples for the dummy load arrangement integrate a portion of the dummy load arrangement into each power amplifier. This facilitates granular control over which portions of the dummy load arrangements are activated (e.g., by the power control arrangement) during the antenna block mode.

The dummy load arrangement may comprise a diverting switch for each of a respective one of a first set of one or more power amplifiers. Each diverting switch is connected between the intermediate node of the respective power amplifier (e.g., the end of first series of amplifying stages) and a ground or return path. FIG. 2 illustrates a suitable example of a power amplifier for the first set of one or more power amplifiers.

The power control arrangement may be configured to activate the dummy arrangement, during the antenna block mode, by controlling which of the one or more diverting switches are activated. Thus, not all of the diverting switches need to be activated during the antenna block mode.

The power control arrangement and the current control arrangement may co-operate together to activate an adequate number of diverting switches to facilitate a desired magnitude of current drawn via the activated diverting switches.

In some examples, the power control arrangement is configured to control which of the one or more diverting switches are activated during the antenna block mode responsive to which of the one or more power amplifiers are activated during the antenna output mode.

For instance, the power control arrangement may be configured to, during the antenna block mode, only activate one or more diverting switches that connect to an intermediate node of a power amplifier that is not activated during the antenna output mode. This provides a cross-calibration technique.

This approach can, for instance, spread a processing workload across the physical space of the power amplifier arrangement, e.g., to reduce a risk of a localized temperature rise and/or reduce a risk of damaging of any individual component of the power amplifier arrangement (e.g., which may otherwise occur if amplifying stages of a same power amplifier were to be continually active throughout the antenna output mode and the antenna block mode).

In other examples, the power control arrangement is configured to, during the antenna block mode, only activate one or more diverting switches that connect to an intermediate node of a power amplifier that is activated during the antenna output mode. For instance, the power control arrangement may be configured to, during the antenna block mode, activate all diverting switches that connect to an intermediate node of a power amplifier that is activated during the antenna output mode.

This approach provides a balanced calibration technique, that significantly reduces any sudden changes in power provided to or drawn through each power amplifier when the power control arrangement switches between the antenna output mode and the antenna block mode, thereby reducing a risk of noise or ringing in any electrical circuitry of at least the power amplifier(s).

At least to reduce power wastage, the current control arrangement may be configured to control the biasing of only the first series of amplifying stages belonging to power amplifiers to which any diverting switch is connected and activated during the antenna block mode.

### Aspects

In addition to the above described aspects, the following aspects are disclosed.
Aspect 1 is a power amplifier arrangement for amplifying signals for transmission by one or more antennae of a wireless transmission arrangement, the power amplifier arrangement comprising: an input interface configured to receive one or more input signals; one or more power amplifiers, each power amplifier being configured to: when activated, amplify a respective input signal of the one or more input signals to generate an amplified input signal, and provide the amplified input signal to a respective antenna of the wireless transmission arrangement; and when deactivated, prevent the provision of the amplified input signal to the respective antenna of the wireless transmission arrangement; a dummy load arrangement configured to: when activated, draw an electrical current from the input interface; and when deactivated, draw no or negligible electrical current from the input interface; a power control arrangement configured to controllably activate and deactivate the one or more power amplifiers and the dummy load arrangement, wherein the power control arrangement is configured to controllably switch between: an antenna output mode, in which the power control arrangement activates at least one power amplifier of the one or more power amplifiers and deactivates the dummy load arrangement; and an antenna block mode, in which the power control arrangement activates the dummy load arrangement and deactivates the one or more power amplifiers; and a calibration arrangement comprising: a sensing arrangement configured to sense a value of one or more power-responsive parameters that change responsive to a power drawn by the one or more power amplifiers when the one or more power amplifiers are activated; and a current control arrangement configured to control, responsive to the sensed value of the one or more power-responsive parameters, a magnitude of the electrical current drawn by the dummy load arrangement when the dummy load arrangement is activated.
Aspect 2 is the power amplifier arrangement of aspect 1, wherein the sensing arrangement is configured to sense a magnitude of an electrical current, drawn by the one or more power amplifiers when activated, as a power responsive parameter of the one or more power responsive parameters.
Aspect 3 is the power amplifier arrangement of aspect 2, wherein the current control arrangement is configured to match the magnitude of the electrical current drawn by the dummy load arrangement when activated to the magnitude of the electrical current drawn by the one or more power amplifiers when activated.
Aspect 4 is the power amplifier arrangement of aspect 2 or 3, wherein the sensing arrangement is configured to: individually sense a current drawn by each power amplifier when activated; and sum the individually sensed current to determine the value of the power-responsive parameter.
Aspect 5 is the power amplifier arrangement of aspect 4, wherein the sensing arrangement comprises: a single sensing element for sensing a magnitude of a current at an input to the sensing element; and a multiplexing arrangement configured to sequentially connect each power amplifier, when activated, to the input to the sensing element to thereby sequentially sense the current drawn by each power amplifier when activated.
Aspect 6 is the power amplifier arrangement of any of aspects 1 to 5, wherein the sensing arrangement is configured to sense a voltage of the power drawn by the one or more power amplifiers, when the one or more power amplifiers are activated, as one of the one or more power responsive parameters.
Aspect 7 is the power amplifier arrangement of aspect 6, wherein the current control arrangement is configured to adjust the magnitude of the electrical current drawn by the dummy load when activated responsive to the voltage of the power drawn by the one or more power amplifiers changing.
Aspect 8 is the power amplifier arrangement of any of aspects 1 to 7, wherein: each power amplifier comprises a first series of one or more amplifying stages connected between the input interface and an intermediate node and a second series of one or more amplifying stages connected between the intermediate node and the respective antenna; the dummy load arrangement comprises a diverting switch for each of a respective one of a first set of one or more power amplifiers, wherein each diverting switch is connected between the intermediate node of the respective power amplifier and a ground or return path; and the current control arrangement is configured to control, responsive to the sensed value of the power-responsive parameter, a biasing of one or more of the first series of amplifying stages of the first set of one or more power amplifiers when the dummy load arrangement is activated.
Aspect 9 is the power amplifier arrangement of aspect 8, wherein the power control arrangement is configured to activate the dummy arrangement, during the antenna block mode, by controlling which of the one or more diverting switches are activated.
Aspect 10 is the power amplifier arrangement of aspect 9, wherein the power control arrangement is configured to control which of the one or more diverting switches are activated during the antenna block mode responsive to which of the one or more power amplifiers are activated during the antenna output mode.
Aspect 11 is the power amplifier arrangement of aspect 10, wherein the power control arrangement is configured to, during the antenna block mode, only activate one or more diverting switches that connect to an intermediate node of a power amplifier that is not activated during the antenna output mode.
Aspect 12 is the power amplifier arrangement of aspect 10, wherein the power control arrangement is configured to, during the antenna block mode, only activate one or more diverting switches that connect to an intermediate node of a power amplifier that is activated during the antenna output mode.
Aspect 13 is the power amplifier arrangement of aspect 12, wherein the power control arrangement is configured to, during the antenna block mode, activate all diverting switches that connect to an intermediate node of a power amplifier that is activated during the antenna output mode.
Aspect 14 is the power amplifier arrangement of any of aspects 9 to 13, wherein the current control arrangement is configured to control the biasing of only the first series of amplifying stages belonging to power amplifiers to which any diverting switch is connected and activated during the antenna block mode.
Aspect 15 is the power amplifier arrangement of any of aspects 1 to 14, wherein the current control arrangement is configured to only change its operation responsive to a calibration signal indicating that a calibration is to be performed.
Aspect 16 is the power amplifier arrangement of aspect 15, further comprising a calibration signal generator configured to generate a calibration signal responsive to the value of at least one of the one or more of the power-responsive parameters breaching a predetermined threshold.
Aspect 17 is the power amplifier arrangement of any of aspects 1 to 16, wherein the sensing arrangement is configured to sense, as one of the one or more power-responsive parameters, a temperature of the power amplifier arrangement.
Aspect 18 is the power amplifier arrangement of any of aspects 1 to 17, wherein the power control arrangement is configured to alternate between operating in the antenna output mode and the antenna block mode.
Aspect 19 is a radar power supply arrangement comprising: the power amplifier arrangement of any of aspects 1 to 18; and a power management arrangement configured to generate an input power for the one or more power amplifiers, wherein the sensing arrangement is configured to sense, as one of the one or more power responsive parameters, a value of a control parameter of the power management arrangement, that changes responsive to a power drawn by the one or more power amplifiers when activated.
Aspect 20 is the radar power supply arrangement of aspect 19, wherein the power management arrangement is configured to generate the input power using pulse-width modulation, wherein the sensing arrangement is configured to sense, as the power-responsive parameter, a PWM parameter that changes responsive to a change in one or more properties of the pulse-width modulation performed by the power management arrangement.

Although specific aspects have been illustrated and described herein, it will be appreciated by those of ordinary skill in the art that a variety of alternate and/or equivalent implementations may be substituted for the specific aspects shown and described without departing from the scope of the present implementation. This application is intended to cover any adaptations or variations of the specific aspects discussed herein. Therefore, it is intended that this implementation be limited only by the claims and the equivalents thereof.

In the context of the present disclosure, an arrangement may be formed as a single cohesive element (e.g., a single semiconductor chip) or across a plurality of separable and distinct elements, e.g., interconnected chips.

It should be noted that the methods and arrangements including its aspects as outlined in the present document may be used stand-alone or in combination with the other methods and arrangement disclosed in this document. In addition, the features outlined in the context of an arrangement are also applicable to a corresponding method, and vice versa. The skilled person would be readily capable of defining and/or adapting a method to perform the function of any herein disclosed arrangement, or combination of arrangements, and vice versa. Furthermore, all aspects of the methods and arrangements outlined in the present document may be arbitrarily combined. In particular, the features of the claims may be combined with one another in an arbitrary manner.

It should be noted that the description and drawings merely illustrate the principles of the proposed methods and arrangements. Those skilled in the art will be able to implement various arrangements that, although not explicitly described or shown herein, embody the principles of the implementation and are included within its spirit and scope. Furthermore, all aspects and implementations outlined in the present document are principally intended expressly to be only for explanatory purposes to help the reader in understanding the principles of the proposed methods and arrangements. Furthermore, all statements herein providing principles, aspects, and implementations of the implementation, as well as specific aspects thereof, are intended to encompass equivalents thereof.

1. A power amplifier arrangement for amplifying signals for transmission by one or more antennae of a wireless transmission arrangement, the power amplifier arrangement comprising:
an input interface configured to receive one or more input signals;
one or more power amplifiers, each power amplifier being configured to:
when activated, amplify a respective input signal of the one or more input signals to generate an amplified input signal, and provide the amplified input signal to a respective antenna of the wireless transmission arrangement; and
when deactivated, prevent a provision of the amplified input signal to the respective antenna of the wireless transmission arrangement;
a dummy load arrangement configured to:
when activated, draw an electrical current from the input interface; and
when deactivated, draw no or negligible electrical current from the input interface;
a power control arrangement configured to controllably activate and deactivate the one or more power amplifiers and the dummy load arrangement, wherein the power control arrangement is configured to controllably switch between:
an antenna output mode, in which the power control arrangement activates at least one power amplifier of the one or more power amplifiers and deactivates the dummy load arrangement; and
an antenna block mode, in which the power control arrangement activates the dummy load arrangement and deactivates the one or more power amplifiers; and
a calibration arrangement comprising:
a sensing arrangement configured to sense a value of one or more power-responsive parameters that change responsive to a power drawn by the one or more power amplifiers when the one or more power amplifiers are activated; and
a current control arrangement configured to control, responsive to the value of the one or more power-responsive parameters, a magnitude of the electrical current drawn by the dummy load arrangement when the dummy load arrangement is activated.

2. The power amplifier arrangement of claim 1, wherein the sensing arrangement is configured to sense, as a power responsive parameter of the one or more power responsive parameters, a magnitude of an electrical current drawn by the one or more power amplifiers when the one or more power amplifiers are activated.

3. The power amplifier arrangement of claim 2, wherein the current control arrangement is configured to match the magnitude of the electrical current drawn by the dummy load arrangement when the dummy load arrangement is activated to the magnitude of the electrical current drawn by the one or more power amplifiers when the one or more power amplifiers are activated.

4. The power amplifier arrangement of claim 2, wherein the sensing arrangement is configured to:
individually sense a current drawn by each power amplifier when the one or more power amplifiers are activated to sense individually sensed currents; and
sum the individually sensed currents to determine a value of the power-responsive parameter.

5. The power amplifier arrangement of claim 4, wherein the sensing arrangement comprises:
a single sensing element for sensing a magnitude of a current at an input to the sensing element; and
a multiplexing arrangement configured to sequentially connect each power amplifier, when activated, to the input of the sensing element to thereby sequentially sense the current drawn by each power amplifier when the one or more power amplifiers activated.

6. The power amplifier arrangement of claim 1, wherein the sensing arrangement is configured to sense a voltage of the power drawn by the one or more power amplifiers, when the one or more power amplifiers are activated, as a power responsive parameter of the one or more power responsive parameters.

7. The power amplifier arrangement of claim 6, wherein the current control arrangement is configured to adjust the magnitude of the electrical current drawn by the dummy load when the dummy load is activated responsive to the voltage of the power drawn by the one or more power amplifiers changing.

8. The power amplifier arrangement of claim 1, wherein:
each power amplifier comprises a first series of one or more amplifying stages connected between the input interface and an intermediate node, and a second series of one or more amplifying stages connected between the intermediate node and the respective antenna;
the dummy load arrangement comprises a diverting switch for each of a respective power amplifier of a first set of one or more power amplifiers, wherein each diverting switch is connected between the intermediate node of the respective power amplifier and a ground or return path; and
the current control arrangement is configured to control, responsive to the value of the one or more power-responsive parameters, a biasing of one or more of the first series of amplifying stages of the first set of one or more power amplifiers when the dummy load arrangement is activated.

9. The power amplifier arrangement of claim 8, wherein the power control arrangement is configured to activate the dummy arrangement, during the antenna block mode, by controlling which of the one or more diverting switches are activated.

10. The power amplifier arrangement of claim 9, wherein the power control arrangement is configured to control which of the one or more diverting switches are activated during the antenna block mode responsive to which of the one or more power amplifiers are activated during the antenna output mode.

11. The power amplifier arrangement of claim 10, wherein the power control arrangement is configured to, during the antenna block mode, only activate one or more diverting switches that connect to an intermediate node of a power amplifier that is not activated during the antenna output mode.

12. The power amplifier arrangement of claim 10, wherein the power control arrangement is configured to, during the antenna block mode, only activate one or more diverting switches that connect to an intermediate node of a power amplifier that is activated during the antenna output mode.

13. The power amplifier arrangement of claim 12, wherein the power control arrangement is configured to, during the antenna block mode, activate all diverting switches that connect to an intermediate node of a power amplifier that is activated during the antenna output mode.

14. The power amplifier arrangement of claim 9, wherein the current control arrangement is configured to control the biasing of only the first series of amplifying stages belonging to power amplifiers to which any diverting switch is connected and activated during the antenna block mode.

15. The power amplifier arrangement of claim 1, wherein the current control arrangement is configured to only change its operation responsive to a calibration signal indicating that a calibration is to be performed.

16. The power amplifier arrangement of claim 15, further comprising;
a calibration signal generator configured to generate a calibration signal responsive to the value of the one or more power-responsive parameters breaching a predetermined threshold.

17. The power amplifier arrangement of claim 1, wherein the sensing arrangement is configured to sense, as one of the one or more power-responsive parameters, a temperature of the power amplifier arrangement.

18. The power amplifier arrangement of claim 1, wherein the power control arrangement is configured to alternate between operating in the antenna output mode and the antenna block mode.

19. A radar power supply arrangement, comprising:
a power amplifier arrangement for amplifying signals for transmission by one or more antennae of a wireless transmission arrangement, the power amplifier arrangement comprising:
an input interface configured to receive one or more input signals:
one or more power amplifiers, each power amplifier being configured to:
when activated, amplify a respective input signal of the one or more input signals to generate an amplified input signal, and provide the amplified input signal to a respective antenna of the wireless transmission arrangement, and
when deactivated, prevent a provision of the amplified input signal to the respective antenna of the wireless transmission arrangement:
a dummy load arrangement configured to:
when activated, draw an electrical current from the input interface, and
when deactivated, draw no or negligible electrical current from the input interface;
a power control arrangement configured to controllably activate and deactivate the one or more power amplifiers and the dummy load arrangement, wherein the power control arrangement is configured to controllably switch between:
an antenna output mode, in which the power control arrangement activates at least one power amplifier of the one or more power amplifiers and deactivates the dummy load arrangement; and
an antenna block mode, in which the power control arrangement activates the dummy load arrangement and deactivates the one or more power amplifiers; and
a calibration arrangement comprising:
a sensing arrangement configured to sense a value of a power-responsive parameter that changes responsive to a power drawn by the one or more power amplifiers when the one or more power amplifiers are activated; and
a current control arrangement configured to control, responsive to the value of the power-responsive parameter, a magnitude of the electrical current drawn by the dummy load arrangement when the dummy load arrangement is activated; and
a power management arrangement configured to generate an input power for the one or more power amplifiers,
wherein the sensing arrangement is configured to sense, as the power responsive parameter, a control parameter of the power management arrangement, that changes responsive to a power drawn by the one or more power amplifiers when activated.

20. The radar power supply arrangement of claim 19, wherein
the power management arrangement is configured to generate the input power using pulse-width modulation (WM), and
wherein the sensing arrangement is configured to sense, as the power-responsive parameter, a PWM parameter that changes responsive to a change in one or more properties of the pulse-width modulation performed by the power management arrangement.
